(19) United States
(12) Patent Application Publication
(10) Pub. No.: US 2009/0009941 A1
(43) Pub. Date: Jan. 8, 2009

(54) HOUSING FOR AN ELECTRONIC DEVICE, ELECTRONIC DEVICE USING THE HOUSING, AND METHOD FOR MAKING THE HOUSING

(75) Inventors: CHE-YUAN HSU, Shindian (TW); RISTO-PEKKA SALMIO, Jarvenpaa (FI); CHENG-WEN SU, Shindian (TW); GANG HUANG, Shenzhen (CN); YAN-MIN WANG, Shenzhen (CN)

Correspondence Address: PCE INDUSTRY, INC.;ATT. CHENG-JU CHIANG, 458 E. LAMBERT ROAD, FULLERTON, CA, 92835, US

(73) Assignees: SHENZHEN FUTAIHONG PRECISION INDUSTRY CO., LTD., ShenZhen City (CN); SUTECH TRADING LIMITED, Tortola (VG)

(21) Appl. No.: 11/959,155

(22) Filed: Dec. 18, 2007

(30) Foreign Application Priority Data
Jul. 4, 2007 (CN) 200710076370.3
Aug. 10, 2007 (CN) 200710075665.9
Aug. 10, 2007 (CN) 200710075666.3

(51) Int. Cl. H05K 5/00; H05K 7/00; G06F 1/16

(52) U.S. Cl. 361/681; 361/679

(57) ABSTRACT

A housing (100) includes a decorative film (10), a supporting sheet (20), and a substrate (30). The decorative film is made of a clear plastic. The supporting sheet is made of a hard material and attached to the decorative film. The substrate is made of a clear material and integrally molded onto the supporting sheet. An electronic device (200) and method of making the housing are also provided.

### CROSS-REFERENCE TO RELATED APPLICATIONS

This application is related to a co-pending U.S. patent application Ser. No. (Attorney Docket No. US14157), entitled “HOUSING FOR AN ELECTRONIC DEVICE AND METHOD FOR MAKING”, by Che-Yuan Hsu et al. This application is also related to another co-pending U.S. patent application Ser. No. (Attorney Docket Nos. US14159), entitled “HOUSING FOR ELECTRONIC DEVICES, ELECTRONIC DEVICE USING THE HOUSING AND METHOD FOR MAKING THE HOUSING”, by Che-Yuan Hsu et al. Such applications have the same assignee as the present application and have been concurrently filed herewith. The above-identified applications are incorporated herein by reference. This application claims all benefits accruing under 35 U.S.C. §119 from China Patent Application No. 200710076370.3 filed on Jul. 4, 2007, China Patent Application No. 200710075666.3 filed on Aug. 10, 2007, and China Patent Application No. 200710075665.9 filed on Aug. 10, 2007 in the China Intellectual Property Office, the disclosures of which are incorporated herein by reference.

### BACKGROUND OF THE INVENTION

1. Field of the Invention

The present invention generally relates to housings, and more particularly, to a housing for an electronic device, and to a method for making the housing using injection molding process.

2. Discussion of the Related Art

An in-mold labeling process, or IML, allows molders to produce a housing with a perfect graphic quality that is unattainable with some post-decorating methods. The housing typically includes a label made from a printed piece of a plastic film and a resin substrate. Photographs, crisp illustrations, and even three-dimensional images can be designed into the label. The molten resin is injection molded onto the label, thereby forming a resin substrate. Thus, the label becomes an integral part of the housing, rather than resting on the outside of the housing.

Nowadays, light weighting housings for electronic devices are desired to meet the requirement of consumers. Thus, the resin substrate of the typical housing should be designed thin enough to meet the lightweight requirement. However, the housing with a thin resin substrate cannot provide enough mechanical support.

Therefore, an improved housing for an electronic devices is desired in order to overcome the above-described shortcomings.

### SUMMARY

In one embodiment thereof, a housing for an electronic device is provided. The housing for an electronic device includes a decorative film, a supporting sheet, and a substrate. The decorative film is made of a clear plastic. The supporting sheet is made of a hard material and attached to the decorative film. The substrate is made of a clear material and integrally molded onto the supporting sheet.

Other advantages and novel features will become more apparent from the following detailed description of preferred embodiments when taken in conjunction with the accompanying drawings.

### BRIEF DESCRIPTION OF THE DRAWINGS

Many aspects of the housing for an electronic device can be better understood with reference to the following drawing. The components in the drawing are not necessarily drawn to scale, the emphasis instead being placed upon clearly illustrating the principles of the housing for an electronic device. Moreover, in the drawing like reference numerals designate corresponding parts throughout the several views.

FIG. 1 is a cross-section view of a preferred embodiment of a housing for an electronic device.

FIG. 2 is a cross-section view of a preferred embodiment of a supporting sheet of the housing using the housing shown in FIG. 1.

FIG. 3 is a cross-section view of a preferred embodiment of an electronic device using the housing shown in FIG. 1.

FIG. 4 is a schematic view of a mold for making the housing in FIG. 1.

FIG. 5 is a schematic view of the mold in FIG. 3 at a close state.

FIG. 6 is a schematic view of the mold in FIG. 3, with the housing molded therein.

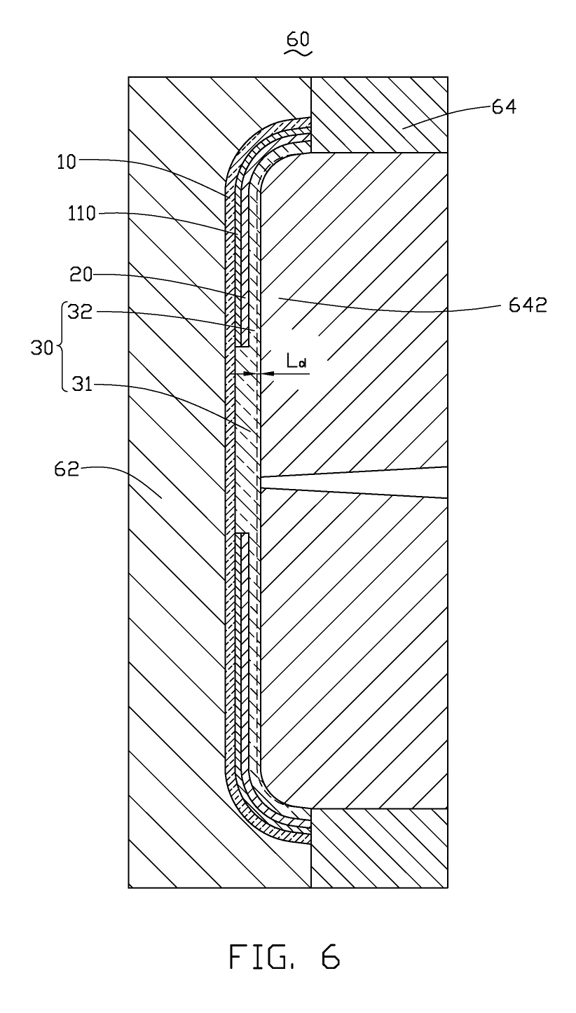

### DETAILED DESCRIPTION OF THE PREFERRED EMBODIMENTS

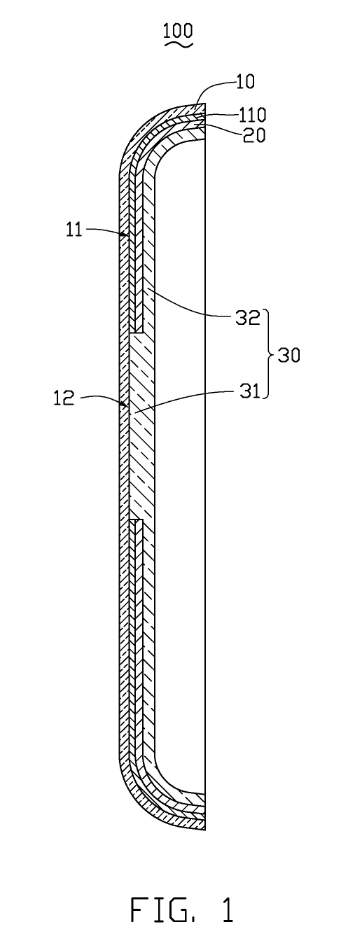

Referring to FIG. 1, in a present embodiment, a housing 100 includes a decorative film 10, a supporting sheet 20, and a substrate 30.

The decorative film 10 can, advantageously, be made of polycarbonate. The decorative film 10 has a surface comprises a decorative section 11 and a display section 12. The decorative section 11 has a decorative coating 110 coated thereon to form marks or figures. The decorative coating 110 can be an ink coating, a paint coating or a metal coating. The display section 12 is capable of transmitting light, as the display section 12 not being coated with the decorative coating 110. Thus, the decorative film 10 is capable of transmitting light through the display section 12. Understandably, the decorative film 10 can also be made of other clear plastic such as polymethyl methacrylate and polystyrene.

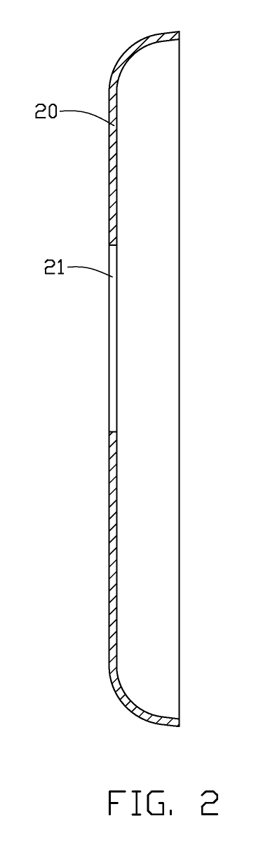

Referring to FIG. 2, the supporting sheet 20 is made of a hard material selected from a group including metal, glass, and ceramic, which have good mechanical strength. The supporting sheet 20 has a view opening 21 formed therein.

The substrate 30 includes a first portion 31 and a second portion 32. The first portion 31 functions as a lens capable of transmitting light. The substrate 30 is made of a clear material selected from a group including polycarbonate, polymethyl methacrylate, polystyrene, or any desired combination thereof. It should be understood, of course, that the supporting sheet 20 could also instead be made of clear silica gel.

The decorative film 10 is attached to the supporting sheet 20 using adhesive, with the decorative coating 110 being placed between the decorative film 10 and the supporting sheet 20, and the display section 12 being aligned with the view opening 21 of the supporting sheet 20. The substrate 30 is injection molded onto the supporting sheet 20 and the decorative film 10, with the first portion 31 being formed in the view opening 21 of the supporting sheet 20 and attached to the display section 12 of the decorative film 10, and the second portion 32 being attached to the supporting sheet 20.

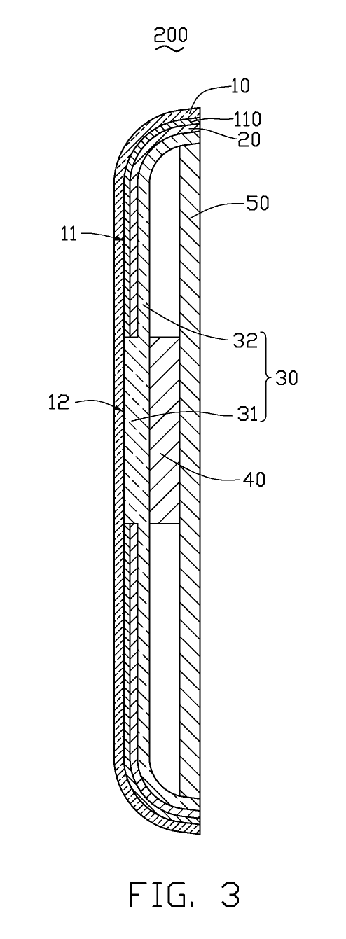

Referring to FIG. 3, the housing 100 can be used in an electronic device 200 (e.g., a mobile phone, digital camera, or PDA), with a display unit 40 and a printed circuit board 50 received therein. The display unit 40 is electrically connected to the printed circuit board 50 so as to display digital information, images, or graphs. The display unit 40 is aligned with the display section 12 of the decorative film 10 and the view opening 21 of the support sheet 20, in manner of that light transmitted from the display unit 40 can transmit through the first portion 31 of the substrate 30 and the display section 12 of the decorative film 10. Thus, the first portion 31 of the substrate 30 attached to the display section 12 functions as a view lens to protect the display unit and capable of transmitting light. The decorative film 10, the supporting sheet 20, and the substrate 30 can be joined together without gap and by a concordant seal. As such, the housing 100 used in the electronic device 200 can obtain a airtight, water-resistant, and dustproof seal.

An exemplary method for making the housing 100 is provided. Firstly, the decorative film 10 is provided. The decorative film 10 can, advantageously, be polycarbonate thin film. The decorative film 10 comprises the decorative section 11 and the display section 12. The decorative section 11 has the decorative coating 110 coated thereon to form marks or figures. The decorative coating 110 can be an ink coating or a paint coating, which can be formed via brushing, spray painting, or screen printing. The decorative coating 110 can also be a metal coating, which is formed via physical vacuum deposition process.

Secondly, referring to FIG. 3, the support sheet 20 is provided. The decorative film 10 is attached onto the support sheet 20 using adhesive, with the decorative coating 110 being placed between the decorative film 10 and the supporting sheet 20, and the display section 12 being aligned with the view opening 20 of the supporting sheet 20.

Thirdly, a mold 60 is provided. The mold 60 includes a female mold 62 and a male mold 64 matingly engageable with the female mold 62. The female mold 62 has a recessed portion 622 formed therein. The male mold 64 has a movable mold core 642 mounted thereon.

Fourthly, the support sheet 20 and the decorative film 10 are fixed into the female mold 62, with the decorative film 10 leaning against the female mold 62.

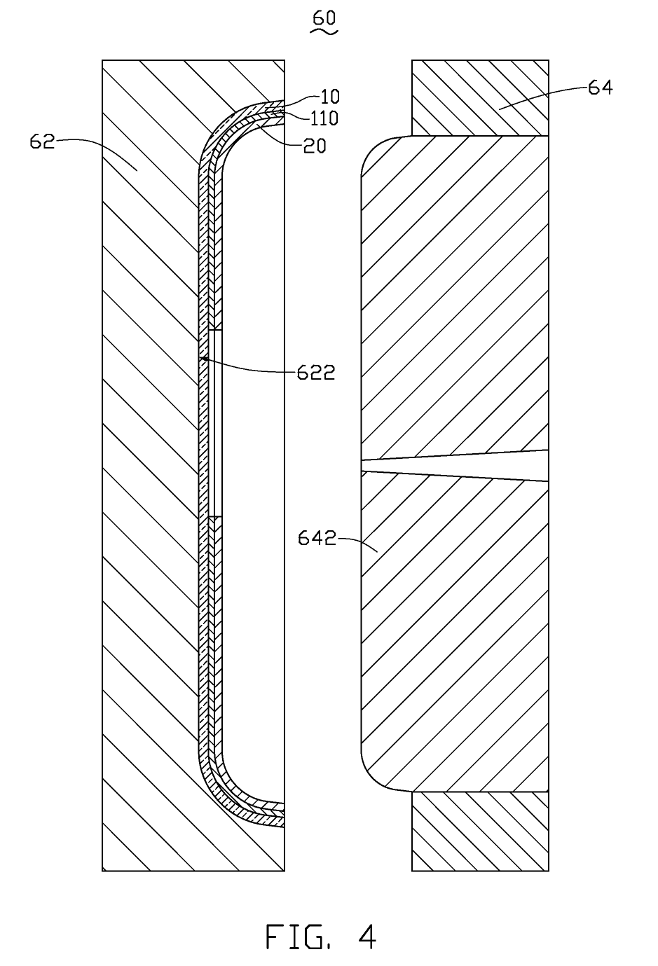

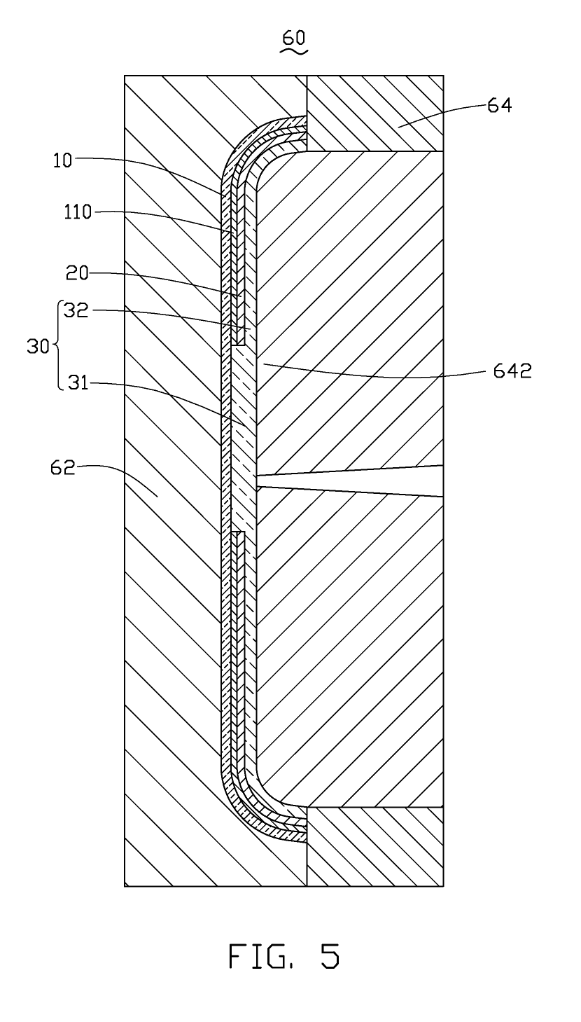

Fifthly, the mold 60 is closed. Referring to FIG. 4 and FIG. 5, a molding cavity is defined between the recessed portion 622 of the female mold 62 and the mold core 642 of the male mold 64. Molten plastic or silica gel is injected into the molding cavity. The molten plastic can be any of transparent plastic material, advantageously chosen from the group including polycarbonate, polymethyl methacrylate, polystyrene, or any desired combination thereof. Thus, referring to FIG. 5, the first portion 31 of the substrate 30 is formed into the view opening of the supporting sheet 20 and onto the decorative film 10, the second portion 32 of the substrate 30 is formed onto the supporting sheet 20. As such, the housing 100 is formed in the mold 60.

Finally, the substrate 30 is compressed in the mold 60 with moving the movable mold core 642 towards the female mold 62. A compression stroke Ld of the mold core 642 is in an approximate range from 0.1 to 0.5 mm. Generally, the decorative film 10 may have a deformation coefficient different from that of the substrate 30. Thus, a stress may be generated during the injection molding of the substrate 30, which may cause birefringence of the decorative film 10 and the substrate 30. The compression process in the final step may remove or reduce the stress generated during the injection molding. It should be understood, of course, that only the first portion 31 of the substrate 30 attached to the display section 12 is compressed in the compression process of the final step. Thus, any potential image aberration caused by the birefringence of the decorative film 10 will be reduced, when the mold 60 is used in the electronic device 200.

It should be understood, however, that even though numerous characteristics and advantages of the present embodiments have been set forth in the foregoing description, together with details of the structures and functions of the embodiments, the disclosure is illustrative only, and changes may be made in detail, especially in matters of shape, size, and arrangement of parts within the principles of the invention to the full extent indicated by the broad general meaning of the terms in which the appended claims are expressed.

What is claimed is:

1. A housing for an electronic device, comprising:
a decorative film made of a clear plastic;
a supporting sheet made of a hard material and attached to the decorative film; and
a substrate integrally molded onto the supporting sheet.

2. The housing as claimed in claim 1, wherein the decorative film has a surface comprising a decorative section and a display section capable of transmitting light, the decorative section having a decorative coating coated thereon.

3. The housing as claimed in claim 2, wherein the decorative coating is an ink coating, a paint coating or a metal coating, the decorative coating being laid between the decorative film and the supporting sheet.

4. The housing as claimed in claim 1, wherein the hard material is selected from a group consisting of glass, metal, and ceramic.

5. The housing as claimed in claim 1, wherein the supporting sheet has a view opening formed therein, a first portion of the substrate being molded in the view opening and integrally molded onto a portion of the decorative film, a second portion of the substrate being integrally molded onto the supporting sheet.

6. The housing as claimed in claim 5, wherein the substrate is made of a transparent plastic material, advantageously chosen from the group consisting of polycarbonate, polymethyl methacrylate, polystyrene, and any desired combination thereof.

7. The housing as claimed in claim 1, wherein the substrate is made of clear silica gel.

8. An electronic device, comprising:
a printed circuit board;
a display unit electrically connected to the printed circuit board;
a housing for an electronic device, comprising:
a decorative film made of a clear plastic, the decorative film having a display section capable of transmitting light;
a supporting sheet made of a hard material and attached to the decorative film, the supporting sheet having a view opening formed therein; and
a substrate made of a clear material and integrally molded onto the supporting sheet, a first portion of the substrate being molded in the view opening and integrally molded onto the display section of the decorative film;
wherein the printed circuit board and the display unit are received in the housing, the display unit is configured to align with the display section of the decorative film and the first portion of the substrate, in manner of that light transmitted from the display unit is capable of transmitting through the display section and the first portion.

9. The electronic device as claimed in claim 8, wherein the decorative film further has a decorative section, the decorative section having a decorative coating formed thereon.

10. The electronic device as claimed in claim 9, wherein the decorative coating is an ink coating, a paint coating or a metal coating.

11. The electronic device as claimed in claim 9, wherein the decorative coating is laid between the decorative film and the supporting sheet.

12. The electronic device as claimed in claim 8, wherein the hard material is selected from a group consisting of glass, metal, and ceramic.

13. The electronic device as claimed in claim 8, wherein the substrate is made of a transparent material, chosen from the group consisting of polycarbonate, polymethyl methacrylate, polystyrene, silica gel, and any desired combination thereof.

14. A method for making a housing, comprising steps of:
providing a decorative film made of a clear plastic;
providing a supporting sheet made of a hard material;
attaching the decorative film onto the support sheet;
fixing the decorative film and the supporting sheet into a mold, with the decorative film leaning against the mold; and
injection molding a substrate onto the supporting sheet in the mold.

15. The method for making a housing as claimed in claim 14, wherein the supporting sheet having a view opening formed therein, a first portion of the substrate being molded into the view opening and onto the decorative film.

16. The method for making a housing as claimed in claim 15, further comprising a step of compressing the first portion of the substrate by using a movable mold core of the mold.

17. The method for making a housing as claimed in claim 14, wherein the decorative film is made of clear polycarbonate thin film, and has a decorative coating formed thereon, the decorative coating being an ink coating, a paint coating or a metal coating.

18. The method for making a housing as claimed in claim 17, wherein the decorative coating is laid between the decorative film and the supporting sheet.

19. The method for making a housing as claimed in claim 14, wherein the substrate is made of a transparent material, chosen from the group consisting of polycarbonate, polymethyl methacrylate, polystyrene, silica gel and any desired combination thereof.
